(19) United States
(12) Patent Application Publication
(10) Pub. No.: US 2024/0186466 A1
(43) Pub. Date: Jun. 6, 2024

(54) LIGHT-EMITTING DEVICE AND MANUFACTURING METHOD THEREOF

(71) Applicant: TCL CHINA STAR OPTOELECTRONICS TECHNOLOGY CO., LTD., Shenzhen (CN)

(72) Inventor: Hongshan YIN, Shenzhen (CN)

(21) Appl. No.: 17/781,138

(22) PCT Filed: May 27, 2022
(86) PCT No.: PCT/CN2022/095509

§ 371 Date: May 31, 2022

(30) Foreign Application Priority Data
May 18, 2022 (CN) 202210543681.0

(51) Int. Cl. H01L 33/50; H01L 33/06

(52) U.S. Cl. CPC H01L 33/507; H01L 33/06; H01L 33/502

(57) ABSTRACT

The present invention discloses a light-emitting device and a manufacturing method thereof. The light-emitting device includes a substrate, a light-emitting structure, and a photoluminescent layer. Wherein the substrate includes a first surface and a second surface opposite to each other. The light-emitting structure is arranged on the first surface, and a side of the light-emitting structure facing the second surface is a light-emitting side of the light-emitting structure. The photoluminescent layer is arranged on the second surface, and the photoluminescent layer is arranged corresponding to the light-emitting structure.

### BACKGROUND

### Field of Invention

The present application relates to a field of display technology, in particular, to a light-emitting device and a manufacturing method thereof.

### Description of Prior Art

With a continuous development of display technology and panel industry, different light-emitting devices have been widely used in display devices. For example, as a new generation of the display technology, mini/micro light-emitting diode (MLED) display technology not only has characteristics of high efficiency, high brightness, high reliability, and extremely fast response time, but also has characteristics of self-illumination without a backlight, small volume, light weight, and energy saving. In an MLED display device, a large number of MLED chips need to be transferred as a display light source.

However, due to manufacturing process and other reasons, for multiple light-emitting devices produced in a same batch and with a same light-emitting structure, although light-emitting colors are same, light-emitting wavelengths can be inconsistent, which will affect quality and display effect of the display devices.

### SUMMARY

The present application provides a light-emitting device and a manufacturing method thereof to solve a technical problem that light-emitting wavelengths of multiple light-emitting devices of a same color are inconsistent in the prior art, thereby affecting quality and light-emitting effect of the light-emitting devices.

The present application provides a light-emitting device, comprising:
a substrate, comprising a first surface and a second surface opposite to each other;
a light-emitting structure, arranged on the first surface, a side of the light-emitting structure facing the second surface is a light-emitting side of the light-emitting structure; and
a photoluminescent layer, arranged on the second surface, the photoluminescent layer is arranged corresponding to the light-emitting structure.

Alternatively, in some embodiments of the present application, the substrate and the light-emitting structure constitute a flip LED chip.

Alternatively, in some embodiments of the present application, the light-emitting structure comprises a first semiconductor layer, a multi quantum well light-emitting layer, a second semiconductor layer, a first electrode, and a second electrode;

wherein the first semiconductor layer is arranged on the first surface, the multi quantum well light-emitting layer and the first electrode are located in a same layer and arranged at intervals on a side of the first semiconductor layer away from the substrate, the first electrode is connected with the first semiconductor layer, the second semiconductor layer is arranged on a side of the multi quantum well light-emitting layer away from the substrate, the second electrode is arranged on a side of the second semiconductor layer away from the substrate, and the second electrode is connected with the second semiconductor layer.

Alternatively, in some embodiments of the present application, the first electrode is arranged on a side of the multi quantum well light-emitting layer or around the multi quantum well light-emitting layer.

Alternatively, in some embodiments of the present application, an orthographic projection of the photoluminescent layer on the substrate covers an orthographic projection of the light-emitting structure on the substrate.

Alternatively, in some embodiments of the present application, the light-emitting structure emits a light with a first wavelength, the photoluminescent layer emits a light with a second wavelength, and the first wavelength is shorter than or longer than the second wavelength.

Alternatively, in some embodiments of the present application, the light-emitting structure emits a blue light or an ultraviolet light, and a material of the photoluminescent layer is quantum dots or an organic light-emitting material.

Alternatively, in some embodiments of the present application, the light-emitting structure emits a red light, and a material of the photoluminescent layer is an up-conversion nanomaterial.

Alternatively, in some embodiments of the present application, a thickness of the photoluminescent layer is greater than 0 microns and less than 200 microns.

Alternatively, in some embodiments of the present application, the light-emitting device further comprises a transparent protective layer, the transparent protective layer is arranged on a side of the photoluminescent layer away from the substrate and covers the photoluminescent layer.

Alternatively, in some embodiments of the present application, the substrate and the light-emitting structure constitute a micro-LED chip or a mini-LED chip.

Alternatively, in some embodiments of the present application, the substrate and the light-emitting structure constitute an OLED device.

Alternatively, in some embodiments of the present application, the light-emitting structure comprises a first pole, an electroluminescent layer, and a second pole; the first pole is arranged on the first surface, the electroluminescent layer is arranged on a side of the first pole away from the substrate, and the second pole is arranged on a side of the electroluminescent layer away from the substrate.

The present application further provides a light-emitting device, comprising:
a substrate, comprising a first surface and a second surface opposite to each other;
a light-emitting structure, arranged on the first surface, a side of the light-emitting structure facing the second surface is a light-emitting side of the light-emitting structure; the substrate and the light-emitting structure constitute a flip micro-LED chip or a mini-LED chip; and
a photoluminescent layer, arranged on the second surface, wherein the photoluminescent layer is arranged corresponding to the light-emitting structure and a thickness of the photoluminescent layer is greater than 0 microns and less than 200 microns.

Alternatively, in some embodiments of the present application, the light-emitting structure comprises a first semiconductor layer, a multi quantum well light-emitting layer, a second semiconductor layer, a first electrode, and a second electrode;
wherein the first semiconductor layer is arranged on the first surface, the multi quantum well light-emitting layer and the first electrode are located in a same layer and arranged at intervals on a side of the first semiconductor layer away from the substrate, the first electrode is connected with the first semiconductor layer, the second semiconductor layer is arranged on a side of the multi quantum well light-emitting layer away from the substrate, the second electrode is arranged on a side of the second semiconductor layer away from the substrate, and the second electrode is connected with the second semiconductor layer.

Alternatively, in some embodiments of the present application, the light-emitting structure emits a light with a first wavelength, the photoluminescent layer emits a light with a second wavelength, and the first wavelength is shorter than or longer than the second wavelength.

Alternatively, in some embodiments of the present application, the light-emitting structure emits a blue light or an ultraviolet light, and a material of the photoluminescent layer is quantum dots or an organic light-emitting material.

Alternatively, in some embodiments of the present application, the light-emitting structure emits a red light, and a material of the photoluminescent layer is an up-conversion nanomaterial.

Accordingly, the present application further provides a manufacturing method of a light-emitting device, comprising:
providing a substrate, wherein the substrate comprises a first surface and a second surface arranged opposite to each other;
forming a plurality of light-emitting structures on the first surface, wherein a side of the light-emitting structures facing the second surface is a light-emitting side of the light-emitting structures;
forming a plurality of photoluminescent layers on the second surface, wherein the photoluminescent layers are arranged in a one-to-one correspondence with the light-emitting structures; and
obtaining a plurality of the light-emitting devices by cutting.

Alternatively, in some embodiments of the present application, a thickness of each of the photoluminescent layers is greater than 0 microns and less than 200 microns.

The present application provides a light-emitting device and a manufacturing method thereof. The light-emitting device comprises a substrate, a light-emitting structure, and a photoluminescent layer. Wherein the substrate has a first surface and a second surface opposite to each other. The light-emitting structure is arranged on the first surface, and a side of the light-emitting structure facing the second surface is a light-emitting side of the light-emitting structure. The photoluminescent layer is arranged on the second surface, and the photoluminescent layer is arranged to be corresponding to the light-emitting structure. By adding the photoluminescent layer on a side of the substrate away from the light-emitting structure, the present application can ensure that light-emitting wavelengths of multiple light-emitting devices with a same light-emitting structure are same, so as to improve quality and light-emitting effect of the light-emitting devices.

### BRIEF DESCRIPTION OF DRAWINGS

In order to explain the technical solutions in the embodiments of the present application more clearly, the following will briefly introduce the drawings needed in the description of the embodiments. Obviously, the drawings in the following description are only some embodiments of the present application. For those skilled in the art, other drawings can be obtained based on these drawings without creative work.

FIG. 1 is a schematic diagram of a first structure of a light-emitting device provided by the present application.

FIG. 2 is a schematic diagram of a second structure of the light-emitting device provided by the present application.

FIG. 3 is a schematic diagram of a third structure of the light-emitting device provided by the present application.

FIG. 4 is a schematic diagram of a fourth structure of the light-emitting device provided by the present application.

FIG. 5 is a schematic flow diagram of a manufacturing method of a light-emitting device provided by the present application.

FIG. 6 is a schematic structural diagram obtained in step 102 of the manufacturing method of the light-emitting device provided by the present application;

FIG. 7 is a schematic structural diagram obtained in step 103 of the manufacturing method of the light-emitting device provided by the present application.

### DETAILED DESCRIPTION OF PREFERRED EMBODIMENTS

In the following, the technical scheme in the embodiment of the present application will be described clearly and completely in combination with the drawings. Obviously, the described embodiments are only a part of the embodiments of the present application, rather than all the embodiments. Based on the embodiments of the present application, all other embodiments obtained by those skilled in the art without creative work fall within the protection scope of the present application.

In the description of the present application, it should be understood that the terms “first” and “second” are only used for descriptive purposes and cannot be understood as indicating or implying relative importance or implicitly indicating the number of indicated technical features. Thus, the features defining “first” and “second” may explicitly or implicitly comprise one or more of the features. Therefore, it cannot be understood as a limitation on the present application.

The present application provides a light-emitting device and a manufacturing method thereof described in detail below. It should be noted that the order of description of the following embodiments does not limit the preferred order of the embodiments of the present application.

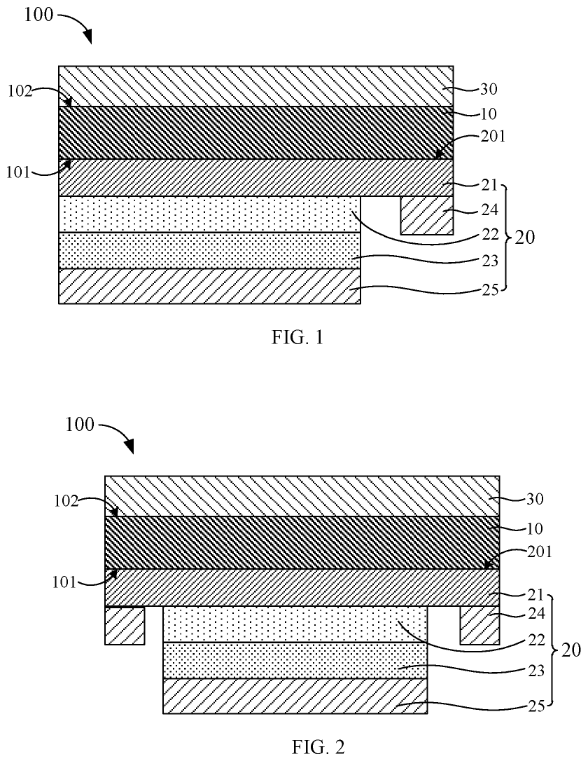

Please refer to FIG. 1, FIG. 1 is a schematic diagram of a first structure of a light-emitting device provided by the present application. In the embodiments of the present application, the light-emitting device 100 comprises a substrate 10, a light-emitting structure 20, and a photoluminescent layer 30.

Wherein the substrate 10 comprises a first surface 101 and a second surface 102 opposite to each other. The light-emitting structure 20 is arranged on the first surface 101. A side of the light-emitting structure 20 facing the second surface 102 is a light-emitting side 201 of the light-emitting structure 20. The photoluminescent layer 30 is arranged on the second surface 102, and the photoluminescent layer 30 is arranged corresponding to the light-emitting structure 20.

Wherein corresponding arrangement of the photoluminescent layer 30 and the light-emitting structure 20 means that an orthographic projection of the photoluminescent layer 30 on the substrate 10 overlaps at least partially with an orthographic projection of the light-emitting structure 20 on the substrate 10, so that at least part of light emitted by the light-emitting structure 20 is incident into the photoluminescent layer 30.

In the embodiments of the present application, the light-emitting structure 20 is provided on the first surface 101 of the substrate 10 and the photoluminescent layer 30 is provided on the second surface 102. Since the side of the light-emitting structure 20 facing the second surface 102 is the light-emitting side 201 of the light-emitting structure 20, the light emitted by the light-emitting structure 20 can be incident into the photoluminescent layer 30, so that the photoluminescent layer 30 emits a light with a corresponding wavelength. Since a manufacturing process of the light-emitting 30 is simple and less affected, the embodiments of the present application can avoid a problem that the light-emitting wavelengths of multiple light-emitting devices 100 with a same light-emitting structure 20 are inconsistent due to a complex manufacturing process of the light-emitting structure 20, so as to improve quality and light-emitting effect of the light-emitting device 100.

In an embodiment of the present application, the light-emitting structure 20 emits a light with a first wavelength. The photoluminescent layer 30 emits a light with a second wavelength. The first wavelength is shorter than the second wavelength. That is, according to a principle of the Stokes shift, under an excitation of the light with the first wavelength, the photoluminescent layer 30 can emit the light with the second wavelength.

Wherein, the light-emitting structure 20 can emit a blue light or an ultraviolet light. In this case, a material of the photoluminescent layer 30 can be quantum dots, an organic light-emitting material, or the like. The photoluminescent layer 30 can emit a light of one or more colors of red light, green light, blue light, yellow light, etc.

For example, when the light-emitting structure 20 emits the blue light, the photoluminescent layer 30 can be excited by the blue light and emit a light with a wavelength longer than a wavelength of the blue light, such as red light, yellow light, green light, and so on. When the light-emitting structure 20 emits ultraviolet light, the photoluminescent layer 30 can be excited by the ultraviolet light and emit a light with a wavelength longer than the ultraviolet wavelength, such as red light, yellow light, green light, blue light, and so on.

Of course, the embodiments of the present application are not limited to this, as long as the first wavelength is shorter than the second wavelength, and the photoluminescent layer 30 can emit the light with the second wavelength under the excitation of the light with the first wavelength.

Specifically, in some embodiments of the present application, the quantum dots can be one or more of Group II-VI compounds, Group III-V compounds, Group II-V compounds, Group III-VI compounds, Group IV-VI compounds, Group I-III-VI compounds, Group II-IV-VI compounds, Group IV monomers, and perovskite quantum dots. Specifically, the quantum dots can be one or more of CdS, CdSe, CdTe, ZnS, ZnSe, ZnTe, HgS, HgSe, HgTe, PbS, PbSe, PbTe, GaP, GaAs, InP, InAs, CdZnSe/ZnS, CdSe/ZnS, CsPbBr₃, and CsPbCl₃.

The organic luminescent materials can be selected from small organic luminescent molecules, luminescent polymers, organic luminescent complexes, etc., which will not be described here one by one.

In the embodiments of the present application, a thickness of the photoluminescent layer 30 is greater than 0 microns and less than 200 microns. For example, the thickness of the photoluminescent layer 30 can be 10 microns, 50 microns, 100 microns, 150 microns, 200 microns, etc. By defining that the thickness of the photoluminescent layer 30 to be greater than 0 microns and less than 200 microns, the embodiments of the present application can fully excite the photoluminescent layer 30 under an irradiation of light emitted by the light-emitting structure 20 and improve light conversion efficiency.

In an embodiment of the present application, the light-emitting structure 20 emits the light with the first wavelength. The photoluminescent layer 30 emits the light with the second wavelength. The first wavelength is longer than the second wavelength. That is, according to a principle of the anti-Stokes shift under an excitation of the light with the first wavelength, the photoluminescent layer 30 can emit the light with the second wavelength.

Wherein, the light-emitting structure 20 can emit red light. In this case, a material of the photoluminescent layer 30 can be an up-conversion nanomaterial or the like. The photoluminescent layer 30 can emit light of one or more colors of green light, blue light, yellow light, etc.

For example, when the light-emitting structure 20 emits red light, the photoluminescent layer 30 can emit green light, blue light, yellow light, and other light with a wavelength shorter than a wavelength of the red light under an excitation of the red light. Of course, the embodiments of the present application are not limited to this, as long as the first wavelength is longer than the second wavelength, and the photoluminescent layer 30 can emit the light with the second wavelength under the excitation of the light with the first wavelength.

Wherein up-conversion nanomaterials are a kind of inorganic nanomaterials doped with rare earth ions. For example, the up-conversion nanomaterials can be NaYF₄:Yb/Er rare earth doped up-conversion nanoparticles, NaYF₄:Yb/Tm doped up-conversion nanoparticles, rare earth NaYF₄:Yb doped up-conversion fluorescent particles, etc., which will not be described here one by one.

In the embodiments of the present application, the substrate 10 and the light-emitting structure 20 can constitute an LED chip, such as micro-LED chip, mini-LED chip, etc. In this case, the light-emitting structure 20 comprises but is not limited to a first semiconductor layer 21, a multi quantum well light-emitting layer 22, a second semiconductor layer 23, a first electrode 24, and a second electrode 25.

Specifically, the first semiconductor layer 21 is arranged on the first surface 101. The multi quantum well light-emitting layer 22 and the first electrode 24 are located in a same layer. The multi quantum well light-emitting layer 22 and the first electrode 24 are arranged at intervals on a side of the first semiconductor layer 21 away from the substrate 10. The first electrode 24 is connected with the first semiconductor layer 21. The second semiconductor layer 23 is arranged on a side of the multi quantum well light-emitting layer 22 away from the substrate 10. The second electrode 25 is arranged on a side of the second semiconductor layer 23 away from the substrate 10. The second electrode 25 is connected to the second semiconductor layer 23.

It can be understood that MLED chips need to grow a semiconductor crystal on a large-sized substrate, and finally separate and transfer a large number of MLED chips through a cutting process. Due to certain differences in chip growth in different batches or different areas of a same batch, luminous wavelengths of MLED chips of a same color are inconsistent, which affects quality of MLED chips and display effect of MLED displays made of MLED chips.

In this regard, in the embodiments of the present application, a layer of photoluminescent layer 30 is coated on a back of the MLED chip, so that multiple MLED chips can emit light with a same wavelength respectively, so as to improve the display effect of the MLED display composed of a large number of MLED chips.

In the embodiments of the present application, a material of the substrate 10 can be selected according to requirements of a device and the light-emitting device 100. For example, the material of the substrate 10 can be sapphire (Al₂O₃), silicon (Si), silicon carbide (SiC), etc.

In the embodiments of the present application, the multi quantum well light-emitting layer 22 can be composed of at least one layer of indium gallium nitride (InGaN)/gallium nitride (GaN) multi quantum well. Of course, the present application is not limited to this.

In the embodiments of the present application, materials of the first electrode 24 and the second electrode 25 can be one or more of Au, Ge, Ni, Cr, Al, Cu, Ti, Pt, Be, Zn, etc.

In the embodiments of the present application, the LED chip is an MLED chip with a flip chip structure. In the MLED chip with the flip chip structure, the substrate 10 is upward, and the first electrode 24 and the second electrode 25 can be directly connected with the substrate (not shown in the figure) through bumps respectively, so as to minimize a thermal path and greatly enhance a thermal conductivity of the MLED chip. In addition, the first electrode 24 and the second electrode 25 no longer occupy more effective luminous areas, a luminous power per unit size is larger and a size is smaller, and a process of wire bonding is reduced, which greatly improves a reliability of MLED chip encapsulation.

In the MLED chip with the flip chip structure, the first semiconductor layer 21 is an N-type semiconductor and the first electrode 24 is an N-type electrode. The second semiconductor layer 23 is a P-type semiconductor and the second electrode 25 is a P-type electrode. The light emitted by the light-emitting structure 20 is emitted from a side of the substrate 10.

For example, when the light-emitting structure 20 emits a blue light or a green light, the substrate 10 can be a sapphire substrate, the first semiconductor layer 21 can be an N-type GaN layer, the second semiconductor layer 23 can be a P-type GaN layer, and the multi quantum well light-emitting layer 22 can be at least one InGaN layer. When the light-emitting structure 20 emits a red light, the first semiconductor layer 21 can be an N-type GaAs layer, the second semiconductor layer 23 can be a P-type GaAs layer, and the multi quantum well light-emitting layer 22 can be AlGaInP. Of course, the structure and a film material of the light-emitting structure 20 in the present application are not limited to this and will not be repeated here one by one.

In the embodiments of the present application, the orthographic projection of the photoluminescent layer 30 on the substrate 10 covers the orthographic projection of the light-emitting structure 20 on the substrate 10.

Since the photoluminescent layer 30 needs to emit the light with the second wavelength under the excitation of the light emitted by the light-emitting structure 20, therefore, in order to improve luminous efficiency of the light-emitting device 100, arranging the orthographic projection of the photoluminescent layer 30 on the substrate 10 to cover an orthographic projection of the multi quantum well light-emitting layer 22 on the substrate 10 can effectively use the light emitted by the light-emitting structure 20 to improve the luminous efficiency of the light-emitting device 100.

Of course, in other embodiments of the present application, since the multi quantum well light-emitting layer 22 and the first electrode 24 are arranged on the substrate 10 at intervals, the orthographic projection of the photoluminescent layer 30 on the substrate 10 can also be arranged within the orthographic projection of the multi quantum well light-emitting layer 22 on the substrate 10, so as to ensure that the photoluminescent layer 30 can be fully excited and reduce consumables of the photoluminescent layer 30.

In the embodiments of the present application, orthographic projections of the first semiconductor layer 21, the multi quantum well light-emitting layer 22, and the second semiconductor layer 23 on the substrate 10 overlap and are all located in an orthographic projection of the first semiconductor layer 21 on the substrate 10. A side of the multi quantum well light-emitting layer 22 away from the first electrode 24 is flush with a side of the first semiconductor layer 21. The first electrode 24 is arranged on a side of the multi quantum well light-emitting layer 22 and is connected in contact with the first semiconductor layer 21.

In the embodiments of the present application, the first electrode 24 is arranged on the side of the multi quantum well light-emitting layer 22, which can increase a relative area of the first semiconductor layer 21, the multi quantum well light-emitting layer 22, and the second semiconductor layer 23, so as to improve a light-emitting area of the light-emitting device 100.

Please refer to FIG. 2, FIG. 2 is a schematic diagram of a second structure of the light-emitting device 100 provided by the present application. A difference from the light-emitting device 100 shown in FIG. 1 is that in the embodiments of the present application, the first electrode 24 is arranged around the multi quantum well light-emitting layer 22.

In the embodiments of the present application, the first electrode 24 is arranged around the multi quantum well light-emitting layer 22, which can improve a contact area between the first electrode 24 and the first semiconductor layer 21. Due to a good thermal conductivity of the first electrode 24, a heat dissipation capacity of the light-emitting device 100 can be improved, so as to prolong a light-emitting life of the light-emitting device 100.

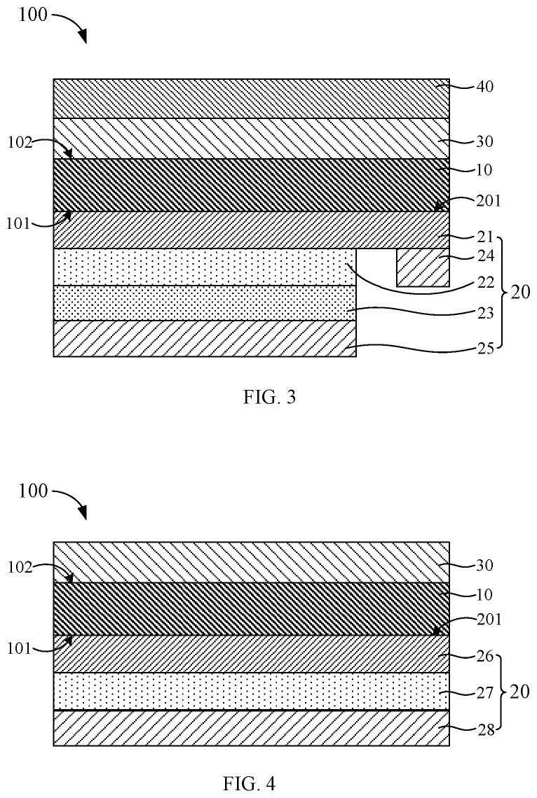

Please refer to FIG. 3, FIG. 3 is a schematic diagram of a third structure of the light-emitting device 100 provided by the present application. A difference from the light-emitting device 100 shown in FIG. 1 is that in the embodiments of the present application, the light-emitting device 100 further comprises a transparent protective layer 40. The transparent protective layer 40 is arranged on a side of the photoluminescent layer 30 away from the substrate 10 and covers the photoluminescent layer 30.

Wherein the transparent protective layer 40 is formed from a cured material comprising a resin composition of a transparent resin and an inorganic filler. For example, the transparent resin can be one or more of silicone resin, epoxy resin, acrylic resin, or polyurethane resin. The inorganic filler can be one or more of alumina, aluminum nitride, titanium oxide, zinc oxide, magnesium oxide, boron nitride, silicon oxide, and silicon nitride. The transparent protective layer 40 can block water and oxygen.

Further, the transparent protective layer 40 can be a transparent thermal conductive layer, which has a thermal conductive role while protecting the photoluminescent layer 30. For example, the transparent thermal conductive layer can be made of transparent materials such as glass, ceramics, and high polymers.

Please refer to FIG. 4, FIG. 4 is a schematic diagram of a fourth structure of the light-emitting device 100 provided by the present application. A difference from the light-emitting device 100 shown in FIG. 1 is that in the embodiments of the present application, the substrate 10 and the light-emitting structure 20 constitute an organic light-emitting diode (OLED) device. In this case, the light-emitting structure 20 comprises a first pole 26, an electroluminescent layer 27, and a second pole 28.

Wherein the first pole 26 is arranged on the first surface 101 of the substrate 10. The electroluminescent layer 27 is arranged on a side of the first pole 26 away from the substrate 10. The second pole 28 is arranged on a side of the electroluminescent layer 27 away from the substrate 10.

Specifically, the substrate 10 can be a flexible substrate or the like. The electroluminescent layer 27 can be a fluorescent material. The first pole 26 can be a transparent cathode. The second pole 28 can be an anode. Light emitted by the light-emitting structure 20 is emitted from the side of the substrate 10 to the light-emitting layer 30.

Of course, the light-emitting structure 20 can further comprise but not limited to a hole injection layer, a hole transport layer, an electron transport layer, and an electron injection layer, etc., which will not be repeated here one by one.

In the embodiments of the present application, a light-emitting structure 20 with an OLED film layer is arranged on the first surface 101 of the substrate 10, and the light-emitting 30 is added on the second surface 102. When multiple OLED devices are made, a problem of inconsistent light-emitting wavelengths of a same batch of OLED devices with a same light-emitting structure 20 due to process and other reasons can also be avoided.

Accordingly, the present application further provides a manufacturing method of a light-emitting device. The manufacturing method of the light-emitting device is to first provide a substrate, wherein the substrate comprises a first surface and a second surface arranged opposite to each other. Then, forming a plurality of light-emitting structures on the first surface, a side of the light-emitting structures facing the second surface is a light-emitting side of the light-emitting structures. Then, forming a plurality of photoluminescent layers on the second surface, the photoluminescent layers are arranged in a one-to-one correspondence with the light-emitting structures. Finally, obtaining a plurality of the light-emitting devices by cutting.

In the embodiments of the present application, by adding a light-emitting layer on a side of the substrate away from the light-emitting structure, the light-emitting layer can be excited by a light of the light-emitting structure to emit a light with a corresponding wavelength. Even if wavelengths of light emitted by a plurality of light-emitting structures deviate during a manufacturing process, since the light-emitting layer is a film layer directly formed on the second surface, therefore, consistency of emission wavelengths of the plurality of light-emitting devices obtained by cutting can be ensured, so as to improve quality of the plurality of light-emitting devices.

Specifically, the embodiments of the present application takes an MLED chip composed of the substrate and the light-emitting structure as an example to explain the manufacturing method of the light-emitting device, but it cannot be understood as limiting the present application.

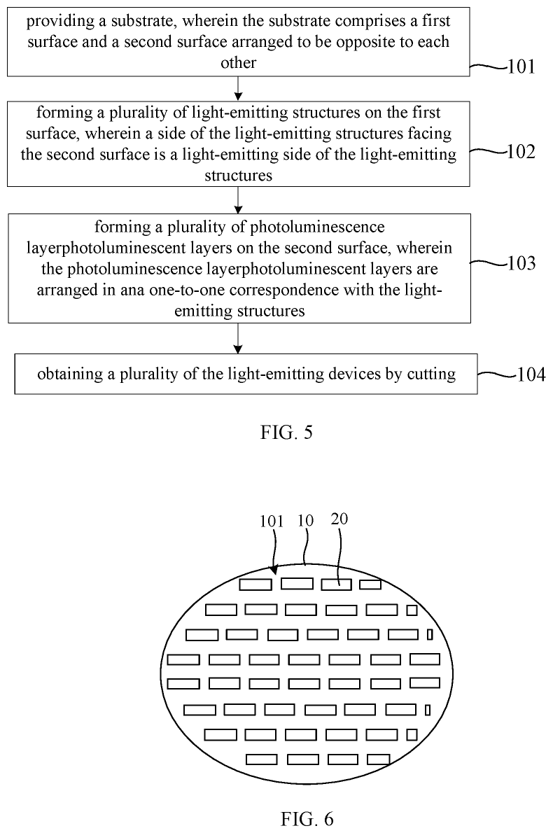

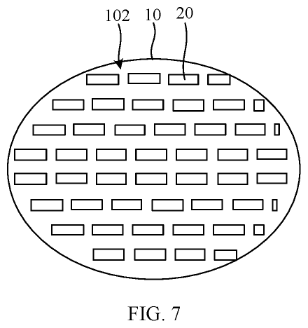

Please refer to FIG. 1, FIGS. 5-7. FIG. 5 is a schematic flow diagram of a manufacturing method of a light-emitting device provided by the present application. FIG. 6 is a schematic structural diagram obtained in step 102 of the manufacturing method of the light-emitting device provided by the present application. FIG. 7 is a schematic structural diagram obtained in step 103 of the manufacturing method of the light-emitting device provided by the present application.

101: providing a substrate, the substrate comprises a first surface and a second surface arranged opposite to each other.

Specifically, the substrate 10 can be sapphire, silicon, silicon carbide, etc. A size of the substrate 10 can be designed according to a process requirement.

102: forming a plurality of light-emitting structures on the first surface, a side of the light-emitting structures facing the second surface is a light-emitting side of the light-emitting structures.

As shown in FIG. 6, a plurality of light-emitting structures 20 arranged at intervals are formed on the first surface 101 of the substrate 10.

Specifically, a first semiconductor layer 21, a multi quantum well light-emitting layer 22, and a second semiconductor layer 23 can be grown successively on the substrate 10 by metal organic chemical vapor deposition. For example, the first semiconductor layer 21 can be an N-type GaN layer, the multi quantum well light-emitting layer 22 can be an InGaN/GaN multi quantum well, and the second semiconductor layer 23 can be a P-type GaN layer to form a GaN epitaxial sheet. Wherein formation processes of the first electrode 24 and the second electrode 25 are well known to those skilled in the art, and structures of the first electrode 24 and the second electrode 25 can refer to the above embodiments, which will not be described in detail here.

Then, the GaN epitaxial sheet is etched to form a plurality of obviously independent light-emitting structures 20.

103: forming a plurality of photoluminescent layers on the second surface, wherein the photoluminescent layers are arranged in a one-to-one correspondence with the light-emitting structures.

As shown in FIG. 7, the substrate 10 forming the light-emitting structure 20 is inverted. A whole layer of photoluminescent layer 30 is formed on the second surface 102 by coating, printing, and other processes. A material of the photoluminescent layer 30 can be quantum dots, an organic light-emitting material, or the like. The photoluminescent layer 30 can emit light of one or more colors of red light, green light, blue light, and yellow light, etc.

Since the whole layer of the photoluminescent layer 30 is formed on the second surface 102 by coating, printing, and other processes, the process is simple and mature, and a film thickness of the photoluminescent layer 30 is uniform. Therefore, light emission wavelengths of the photoluminescent layers 30 everywhere on the second surface 102 are same.

In the embodiments of the present application, the photoluminescent layer 30 on each substrate 10 can emit only one color of light. That is, the photoluminescent layer 30 on each substrate 10 is formed of a same light-emitting material. For example, the photoluminescent layer 30 on one substrate 10 can emit blue light, the photoluminescent layer 30 on another substrate 10 can emit red light, and the photoluminescent layer 30 on yet another substrate 10 can emit green light. Thus, a preparation efficiency of the light-emitting device 100 and a transfer efficiency of the light-emitting device 100 can be improved.

In the embodiments of the present application, a thickness of the photoluminescent layer 30 is greater than 0 microns and less than 200 microns. For example, the thickness of the photoluminescent layer 30 can be 10 microns, 50 microns, 100 microns, 150 microns, 200 microns, etc.

The embodiments of the present application defines that the thickness of the photoluminescent layer 30 is greater than 0 microns and less than 200 microns. On one hand, within a thickness range, a uniformity of the film thickness of the photoluminescent layer 30 obtained by coating or printing can be ensured, preparation difficulty is reduced, and wavelength consistency of a plurality of the light-emitting devices 100 is further improved. On the other hand, the photoluminescent layer 30 can be fully excited under an irradiation of the light emitted by the light-emitting structure 20, so as to improve light conversion efficiency.

In some embodiments, as shown in FIG. 3, a transparent protective layer 40 can also be formed on a side of the photoluminescent layer 30 away from the substrate 10. For details, please refer to the above embodiments, which will not be repeated here one by one.

104: obtaining a plurality of the light-emitting devices by cutting.

Specifically, a semi-finished product obtained in step 103 is cut by laser cutting and other methods to obtain a plurality of independent light-emitting devices 100.

It can be understood that since the photoluminescent layer 30 on each substrate 10 can emit light with only one color, emission wavelengths of the plurality of light-emitting devices 100 obtained by cutting a same substrate 10 are same.

The manufacturing method of the light-emitting device 100 provided by the embodiments of the present application is simple, and the emission wavelengths of the plurality of light-emitting devices 100 are equal. Further, when a large number of light-emitting devices 100 made by the manufacturing method are made into an MLED display, full-color display can be realized and display effect of the MLED display device can be improved.

The light-emitting device and manufacturing method thereof provided in the present application is described in detail above. And in this paper, specific examples are applied to explain the principle and implementation mode of the application. The above embodiments are only examples of the implementation of the present invention. It must be noted that the disclosed embodiments do not limit the scope of the present invention. On the contrary, the modification and equalization of the spirit and scope comprised in the claims are comprised in the scope of the invention.

What is claimed is:

1. A light-emitting device, comprising:
a substrate, comprising a first surface and a second surface opposite to each other;
a light-emitting structure, arranged on the first surface, a side of the light-emitting structure facing the second surface is a light-emitting side of the light-emitting structure; and
a photoluminescent layer, arranged on the second surface, the photoluminescent layer is arranged corresponding to the light-emitting structure.

2. The light-emitting device according to claim 1, wherein the substrate and the light-emitting structure constitute a flip LED chip.

3. The light-emitting device according to claim 2, wherein the light-emitting structure comprises a first semiconductor layer, a multi quantum well light-emitting layer, a second semiconductor layer, a first electrode, and a second electrode;
wherein the first semiconductor layer is arranged on the first surface, the multi quantum well light-emitting layer and the first electrode are located in a same layer and arranged at intervals on a side of the first semiconductor layer away from the substrate, the first electrode is connected with the first semiconductor layer, the second semiconductor layer is arranged on a side of the multi quantum well light-emitting layer away from the substrate, the second electrode is arranged on a side of the second semiconductor layer away from the substrate, and the second electrode is connected with the second semiconductor layer.

4. The light-emitting device according to claim 3, wherein the first electrode is arranged on a side of the multi quantum well light-emitting layer or around the multi quantum well light-emitting layer.

5. The light-emitting device according to claim 1, wherein an orthographic projection of the photoluminescent layer on the substrate covers an orthographic projection of the light-emitting structure on the substrate.

6. The light-emitting device according to claim 1, wherein the light-emitting structure emits a light with a first wavelength, the photoluminescent layer emits a light with a second wavelength, and the first wavelength is shorter than or longer than the second wavelength.

7. The light-emitting device according to claim 6, wherein the light-emitting structure emits a blue light or an ultraviolet light, and a material of the photoluminescent layer is quantum dots or an organic light-emitting material.

8. The light-emitting device according to claim 6, wherein the light-emitting structure emits a red light, and a material of the photoluminescent layer is an up-conversion nanomaterial.

9. The light-emitting device according to claim 1, wherein a thickness of the photoluminescent layer is greater than 0 microns and less than 200 microns.

10. The light-emitting device according to claim 1, wherein the light-emitting device further comprises a transparent protective layer, the transparent protective layer is arranged on a side of the photoluminescent layer away from the substrate and covers the photoluminescent layer.

11. The light-emitting device according to claim 1, wherein the substrate and the light-emitting structure constitute a micro-LED chip or a mini-LED chip.

12. The light-emitting device according to claim 1, wherein the substrate and the light-emitting structure constitute an OLED device.

13. The light-emitting device according to claim 12, wherein the light-emitting structure comprises a first pole, an electroluminescent layer, and a second pole; the first pole is arranged on the first surface, the electroluminescent layer is arranged on a side of the first pole away from the substrate, and the second pole is arranged on a side of the electroluminescent layer away from the substrate.

14. A light-emitting device, comprising:
a substrate, comprising a first surface and a second surface opposite to each other;
a light-emitting structure, arranged on the first surface, a side of the light-emitting structure facing the second surface is a light-emitting side of the light-emitting structure; the substrate and the light-emitting structure constitute a flip micro-LED chip or a mini-LED chip; and
a photoluminescent layer, arranged on the second surface, wherein the photoluminescent layer is arranged corresponding to the light-emitting structure and a thickness of the photoluminescent layer is greater than 0 microns and less than 200 microns.

15. The light-emitting device according to claim 14, wherein the light-emitting structure comprises a first semiconductor layer, a multi quantum well light-emitting layer, a second semiconductor layer, a first electrode, and a second electrode;
wherein the first semiconductor layer is arranged on the first surface, the multi quantum well light-emitting layer and the first electrode are located in a same layer and arranged at intervals on a side of the first semiconductor layer away from the substrate, the first electrode is connected with the first semiconductor layer, the second semiconductor layer is arranged on a side of the multi quantum well light-emitting layer away from the substrate, the second electrode is arranged on a side of the second semiconductor layer away from the substrate, and the second electrode is connected with the second semiconductor layer.

16. The light-emitting device according to claim 14, wherein the light-emitting structure emits a light with a first wavelength, the photoluminescent layer emits a light with a second wavelength, and the first wavelength is shorter than or longer than the second wavelength.

17. The light-emitting device according to claim 16, wherein the light-emitting structure emits a blue light or an ultraviolet light, and a material of the photoluminescent layer is quantum dots or an organic light-emitting material.

18. The light-emitting device according to claim 16, wherein the light-emitting structure emits a red light, and a material of the photoluminescent layer is an up-conversion nanomaterial.

19. A manufacturing method of a light-emitting device, comprising:
providing a substrate, wherein the substrate comprises a first surface and a second surface arranged opposite to each other;
forming a plurality of light-emitting structures on the first surface, wherein a side of the light-emitting structures facing the second surface is a light-emitting side of the light-emitting structures;
forming a plurality of photoluminescent layers on the second surface, wherein the photoluminescent layers are arranged in a one-to-one correspondence with the light-emitting structures; and
obtaining a plurality of the light-emitting devices by cutting.

20. The manufacturing method of the light-emitting device according to claim 19, wherein a thickness of each of the photoluminescent layers is greater than 0 microns and less than 200 microns.
